(19) United States
(12) Patent Application Publication
(10) Pub. No.: US 2002/0032958 A1
(43) Pub. Date: Mar. 21, 2002

(54) Method of manufacturing magnetic head assembly

(76) Inventor: Masaaki Habata, Higashiyamato-shi (JP)

Correspondence Address: Pillsbury Winthrop LLP, Ninth Floor, East Tower, 1100 New York Avenue, N.W., washington, DC, 20005-3918, US

(21) Appl. No.: 09/955,094

(22) Filed: Sep. 19, 2001

(30) Foreign Application Priority Data
Sep. 21, 2000 (JP) 2000-287694

(51) Int. Cl. G11B 5/127; H04R 31/00; H05K 3/20

(52) U.S. Cl. 29/603.04; 29/854; 29/831

(57) ABSTRACT

In a method of manufacturing a magnetic head assembly, after mounting a slider with a magnetic head formed thereon onto a wiring pattern of a trace, the trace with the slider mounted thereon is fixed onto a suspension and arm.

### CROSS-REFERENCE TO RELATED APPLICATIONS

This application is based upon and claims the benefit of priority from the prior Japanese Patent Application No. 2000-287694, filed Sep. 21, 2000, the entire contents of which are incorporated herein by reference.

### BACKGROUND OF THE INVENTION

1. Field of the Invention

The present invention relates to a method of manufacturing a magnetic head assembly for use in a magnetic disk apparatus.

2. Description of the Related Art

A magnetic disk apparatus is generally provided with a magnetic disk disposed in a case, spindle motor for supporting and rotating the magnetic disk, and magnetic head assembly including a magnetic head for reading/writing information with respect to the magnetic disk.

The magnetic head assembly includes a slider with the magnetic head formed thereon, a suspension for supporting the slider, and an arm for supporting the suspension. A wiring pattern is fixed on the suspension and arm, the slider is attached to the wiring, and the magnetic head is electrically connected to the wiring pattern.

The magnetic head assembly is rotatably supported by a bearing assembly, and rotated by a voice coil motor, so that the magnetic head can be moved to an arbitrary position on the magnetic disk.

In general, when the magnetic head assembly is manufactured, the wiring pattern is first fixed onto the arm and suspension, and subsequently the slider with the magnetic head formed thereon is bonded to a tongue portion of the wiring pattern by using an adhesive. Subsequently, electrodes provided on the slider are electrically connected to pad portions disposed on the wiring pattern, so that the magnetic head assembly is manufactured.

Mainly an ultrasonic bonding called a gold ball bonding (GBB) is used to connect the slider electrode to the wiring pattern pad portion. Moreover, when this ultrasonic bonding is performed, the tongue portion of the wiring pattern needs to be supported from a back side in order to prevent the wiring pattern from being deformed. Here, since the wiring pattern is fixed onto the suspension, the tongue portion cannot directly be supported. To solve this problem, while an opening is formed beforehand in a position opposite to the tongue portion of the wiring pattern in a tip end of the suspension, and the tongue portion is supported by a jig through the opening, the ultrasonic bonding is performed.

However, when the opening for passing the jig is formed in the tip end of the suspension as described above, a width of the suspension cannot be reduced less than a certain constant width in order to maintain a mechanical strength of the suspension. Therefore, design of the magnetic head assembly is restricted. Moreover, with a large width of the tip end of the suspension, a range in which the magnetic head can move is reduced in an inner peripheral portion of the magnetic disk.

Furthermore, steps of forming the opening and disposing the jig through the opening are necessary during the manufacturing of the magnetic head assembly. This complicates the manufacturing steps and increases a manufacturing cost.

### BRIEF SUMMARY OF THE INVENTION

The present invention has been developed in consideration of the aforementioned problems, and an object of an aspect of the present invention is to provide a method of manufacturing a magnetic head assembly in which a degree of freedom in designing a suspension can be increased and a manufacturing cost can be reduced.

According to an aspect of the present invention, there is provided a method of manufacturing a magnetic head assembly comprising: forming a wiring pattern; mounting a slider having a magnetic head on the wiring pattern; and fixing the wiring pattern with the slider mounted thereon onto a suspension and an arm.

Moreover, according to another aspect of the present invention, there is provided a method of manufacturing a magnetic head assembly: forming a wiring pattern sheet having a plural sets of wiring patterns; mounting a slider having a magnetic head on each wiring pattern of the wiring pattern sheet; cutting the wiring pattern with the slider mounted thereon out of the wiring pattern sheet; and fixing the cut wiring pattern onto a suspension and an arm.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view showing an HDD including a magnetic head assembly manufactured by a manufacturing method according to an embodiment of the present invention;

FIG. 2 is a perspective view showing the magnetic head assembly;

FIG. 3 is a plan view of a wiring pattern sheet in which a plural sets of wiring patterns are formed in a manufacturing process of the magnetic head assembly;

FIG. 4 is a partially enlarged plan view of each wiring pattern in the wiring pattern sheet;

FIG. 5 is a perspective view showing that a slider is mounted on the wiring pattern in a manufacturing step of the magnetic head assembly;

FIG. 6 is a perspective view showing a trace with the slider mounted on the wiring pattern;

FIG. 7 is a perspective view showing the trace, suspension, and arm constituting the magnetic head assembly; and

FIG. 8 is a perspective view of the trace on which the slider and head amplifier IC are mounted on the wiring pattern in the manufacturing method of the magnetic head assembly according to another embodiment of the present invention.

### DETAILED DESCRIPTION OF THE INVENTION

A method of manufacturing a magnetic head assembly according to an embodiment of the present invention will be described in detail with reference to the drawings.

First, a constitution of a hard disk drive (hereinafter referred to as HDD) will be described as a magnetic disk apparatus including the magnetic head assembly manufactured by the manufacturing method of the present embodiment.

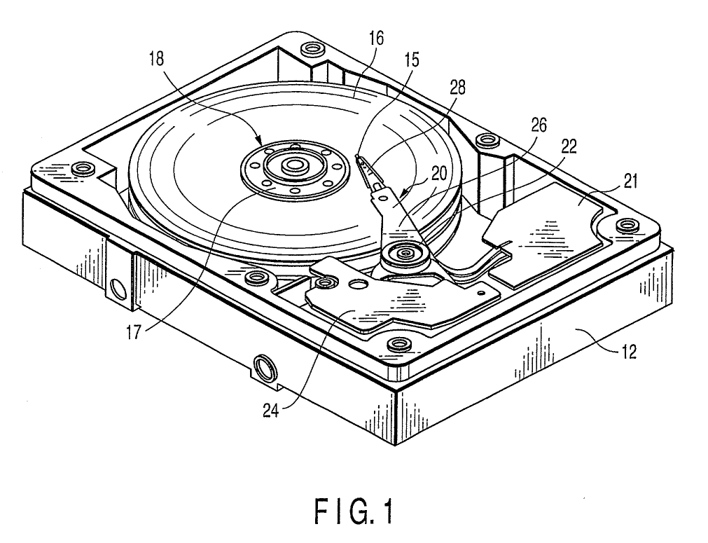

As shown in FIG. 1, the HDD includes a case 12 formed in a rectangular box shape having an upper opening, and a top cover (not shown) fixed to the case via a plurality of screws to close the upper opening of the case.

Contained in the case 12 are, for example, three magnetic disks 16 as a magnetic recording medium, a spindle motor 18 for supporting and rotating the magnetic disks 16, a plurality of magnetic head assemblies 20 each provided with a magnetic head 15 for reading/writing information with respect to the magnetic disk 16, a bearing assembly 22 for rotatably supporting these magnetic head assemblies 20 with respect to the magnetic disk 16, a voice coil motor (hereinafter referred to as VCM) 24 for rotating and positioning the magnetic head assemblies 20, and a board unit 21.

Moreover, a printed circuit board (not shown) for controlling an operation of the spindle motor 18, VCM 24, and magnetic heads 15 via the substrate unit 21 is screwed to the outer surface of the bottom surface of the case 12.

Each magnetic disk 16 has a diameter of 65 mm (2.5 inches), and includes magnetic recording layers on upper and lower surfaces thereof. The magnetic disks 16 are coaxially fitted to a hub (not shown) of the spindle motor 18, and held by a clamp spring 17. Moreover, three magnetic disks 16 are rotated at a predetermined speed by the spindle motor 18.

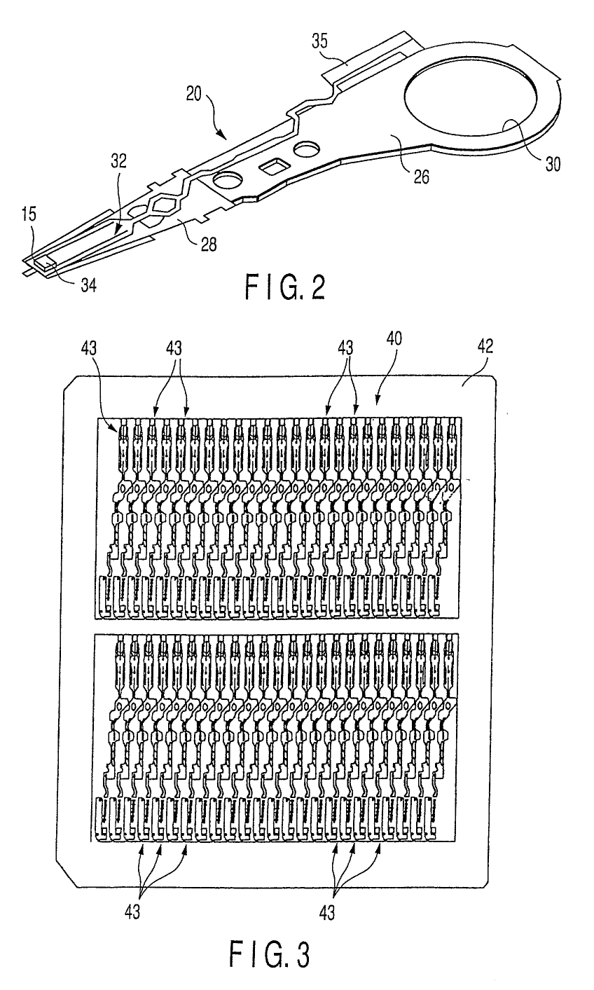

As shown in FIGS. 1 and 2, the magnetic head assembly 20 includes an arm 26, and a suspension 28 whose base end is fixed to a distal end of the arm 26 by spot welding or bonding and which extends from the arm. The arm 26 is formed, for example, in a thin flat plate shape having a plate thickness of about 250 μm by a stainless steel based material such as SUS304, and a circular through hole 30 is formed in a base end of the arm. The suspension 28 is constituted of a thin plate having a thickness of 50 to 75 μm. Additionally, the suspension 28 may be formed integrally with the arm by the same material as that of the arm 26.

Moreover, the magnetic head assembly 20 includes a trace 32 welded onto the suspension 28 and arm 26 and having a wiring pattern, and a slider 34 mounted on the trace 32 and supported by the distal end of the suspension 28. Furthermore, the magnetic head 15 as an electromagnetic converting element is formed on the tip end of the slider 34.

The slider 34 is pressed toward the magnetic disk by a function of the suspension 28 as a leaf spring, and has a function of allowing the magnetic head 15 to float above the magnetic disk surface by a substantially constant distance by a pneumatic pressure generated by rotation of the magnetic disk 16. Moreover, as the magnetic head 15, for example, a composite separating type magnetic head including a reproducing (reading) magnetoresistive effect element (MR element) and a recording (writing) thin film head is used.

The magnetic head 15 is electrically connected to the board unit 21 via the trace 32. The trace 32 includes a stainless steel plate and a relaying flexible wiring plate (hereinafter referred to as a relay FPC) formed on the stainless steel plate and having the wiring pattern, and is formed in a thin strip shape. The trace 32 is fixed onto the suspension 28 and arm 26, and extends to a middle portion of the arm 26 from the distal end of the suspension 28. A soldered pad portion 35 formed on the base end of the trace extends outwardly from the arm 26.

The relay FPC of the trace 32 has a wiring pattern, for example, of four conductor wires, and the conductor wires include pad portions for connecting, for example, four electrodes of the magnetic head 15, as described later. Moreover, the soldered pad portion 35 of the trace 32 constitutes a connection end of the trace 32, and has electrode pads corresponding to the conductor wires. As shown in FIG. 1, the soldered pad portion 35 is connected to a main FPC extending from the substrate unit 21.

The magnetic head assembly 20 constituted in this manner is attached to the bearing assembly by passing the hub of the bearing assembly 22 through the through hole 30 of the arm 26, and rotated around the bearing assembly by the VCM 24. Moreover, when the magnetic head assembly 20 rotates, the magnetic head 15 supported by the tip end of the suspension 28 is moved substantially in a radial direction of the magnetic disk 16.

A manufacturing method of the magnetic head assembly constituted as described above will be described.

First, as shown in FIG. 3, a wiring pattern sheet 40 is formed on a stainless steel substrate 42. The pattern sheet 40 includes a multiplicity of wiring patterns 43 which have the same shape and arranged side by side. The wiring pattern sheet 40 is formed similarly as a usual FPC by disposing a copper foil on a sputtered/formed insulating layer, photoetching or otherwise patterning the copper foil in a predetermined shape, and subsequently superposing an insulating layer again.

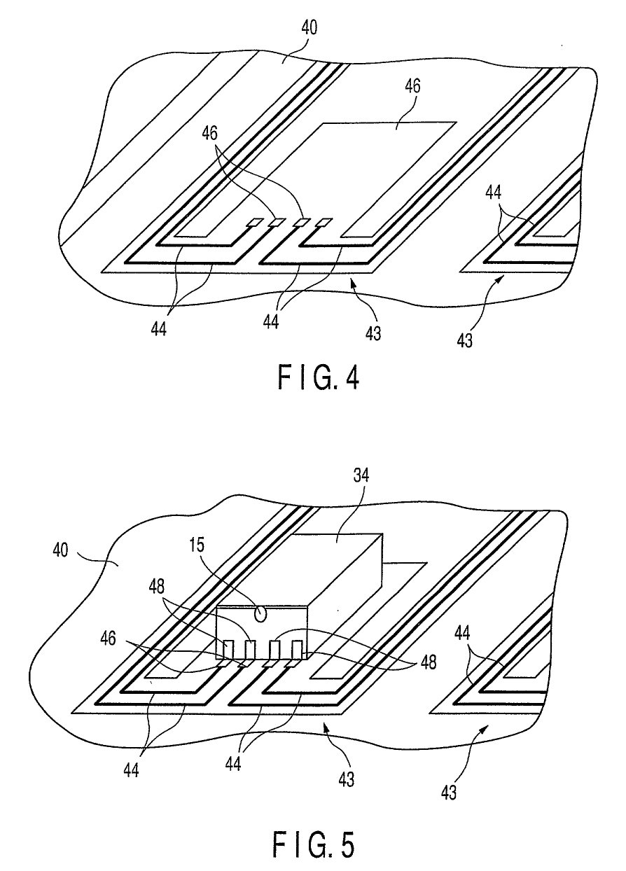

As shown in FIG. 4, each wiring pattern 43 has, for example, four conductor wires 44, and tip ends of the conductor wires extend to electrode pads 46 disposed on a tongue forming portion 45 of the wiring pattern sheet 40.

Subsequently, as shown in FIG. 5, after the slider 34 with the magnetic head 15 formed beforehand thereon is bonded onto the tongue forming portion 45 of the wiring pattern sheet 40, for example, by an epoxy-based adhesive, the electrode pads 46 disposed on the wiring pattern 43 are electrically connected to the respective electrodes 48 disposed on the slider 34 by GBB, and the like. Thereby, the wiring pattern sheet 40 having a multiplicity of wiring patterns 43 with the respective sliders 34 mounted thereon is formed.

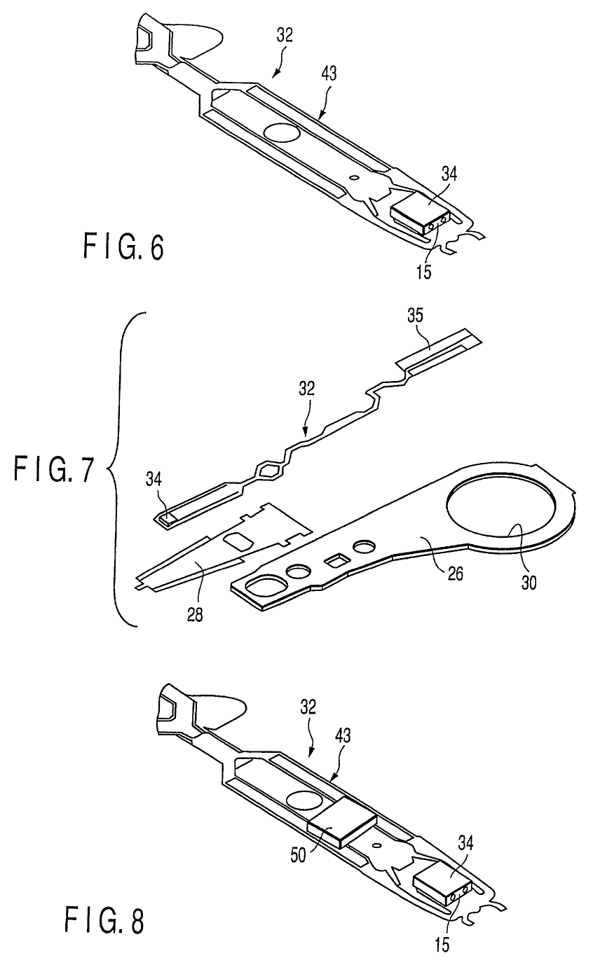

Thereafter, each wiring pattern 43 is cut out of the wiring pattern sheet 40 together with the stainless steel substrate 42, so that the trace 32 of the predetermined shape including the wiring pattern 43 with the slider 34 mounted thereon is obtained as shown in FIG. 6.

Then, as shown in FIG. 7, the trace 32 with the slider 34 mounted thereon is bonded to the suspension 28 and arm 26 by laser welding, and the like, so that the magnetic head assembly 20 is completed as shown in FIG. 2.

According to the manufacturing method of the magnetic head assembly constituted as described above, after the slider is mounted on the wiring pattern, the wiring pattern is fixed to the suspension and arm. In this constitution, it is unnecessary to form the opening for passing the jig beforehand in the suspension, so that the degree of freedom in designing the suspension can be increased. Moreover, since the opening is omitted in this manner, the tip end of the suspension can be formed narrower. In this case, the magnetic head can be moved toward the inner periphery of the magnetic disk in the HDD as compared with the conventional art. This constitution is advantageous in increasing the memory capacity of the HDD.

Furthermore, the step of forming the opening can be omitted, it is unnecessary to dispose the jig through the opening. Thus, the manufacturing cost can be reduced.

Moreover, the sliders 34 can be bonded to the multiplicity of wiring patterns formed on the wiring pattern sheet, and the slider electrodes can be connected to the electrode pads. Therefore, the manufacturing efficiency can largely be enhanced as compared with the conventional art in which the slider is mounted on each wiring pattern fixed onto the suspension.

Additionally, the manufacturing method of the present invention can also be applied to the manufacturing of the magnetic head assembly including a head amplifier IC. That is, as in another embodiment shown in FIG. 8, the slider 34 and head amplifier IC 50 are mounted on the wiring pattern 43 of the trace 32, and the magnetic head 15 formed on the slider is electrically connected to the head amplifier IC via the wiring pattern. Moreover, the trace 32 with the slider 34 and head amplifier IC 50 mounted thereon is fixed onto the suspension and arm by laser welding, and the like, so that the magnetic head assembly can be constituted.

In this case, as in the aforementioned embodiment, after forming the wiring pattern sheet including a large number of wiring patterns, and mounting the slider and head amplifier IC on each wiring pattern, each wiring pattern 43 is cut out. The trace 32 having the predetermined shape with the slider 34 and head amplifier IC mounted thereon may be formed in this manner.

Furthermore, even in another embodiment constituted as described above, it is unnecessary to form the opening for passing the jig beforehand in the suspension. Therefore, the degree of freedom in designing the suspension can be increased, and the manufacturing cost can be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

For example, a concrete shape of the wiring pattern, a method of mounting the slider onto the wiring pattern, and the like can be variously selected as the occasion demands. Moreover, in the aforementioned embodiments, the slider and head amplifier IC are mounted on each wiring pattern of the wiring pattern sheet. However, after cutting each wiring pattern out of the wiring pattern sheet to form the trace, the slider or the head amplifier IC may be mounted on each wiring pattern.

What is claimed is:

1. A method of manufacturing a magnetic head assembly comprising:
forming a wiring pattern;
mounting a slider having a magnetic head on the wiring pattern; and
fixing the wiring pattern with the slider mounted thereon onto a suspension and an arm.

2. A method of manufacturing a magnetic head assembly according to claim 1, wherein the mounting the slider comprises fixing the slider onto the wiring pattern, and subsequently electrically connecting the magnetic head to the wiring pattern.

3. A method of manufacturing a magnetic head assembly comprising:
forming a wiring pattern sheet having a plural sets of wiring patterns;
mounting a slider having a magnetic head on each wiring pattern of the wiring pattern sheet;
cutting the wiring pattern with the slider mounted thereon out of the wiring pattern sheet; and
fixing the cut wiring pattern onto a suspension and an arm.

4. A method of manufacturing a magnetic head assembly according to claim 3, wherein the mounting the slider comprises fixing the slider onto the wiring pattern, and subsequently electrically connecting the magnetic head to the wiring pattern.

5. A method of manufacturing a magnetic head assembly comprising:
forming a wiring pattern;
mounting a slider having a magnetic head and a head amplifier IC on the wiring pattern; and
fixing the wiring pattern with the slider and the head amplifier IC mounted thereon onto a suspension and an arm.

6. A method of manufacturing a magnetic head assembly according to claim 5, wherein the mounting the slider comprises fixing the slider onto the wiring pattern, and subsequently electrically connecting the magnetic head to the wiring pattern.

7. A method of manufacturing a magnetic head assembly comprising:
forming a wiring pattern sheet having a plural sets of wiring patterns;
mounting a slider having a magnetic head and a head amplifier IC on each wiring pattern of the wiring pattern sheet;
cutting the wiring pattern with the slider and the head amplifier IC mounted thereon out of the wiring pattern sheet; and
fixing the cut wiring pattern onto a suspension and an arm.

8. A method of manufacturing a magnetic head assembly according to claim 7, wherein the mounting the slider comprises fixing the slider onto the wiring pattern, and subsequently electrically connecting the magnetic head to the wiring pattern.
